(19) United States
(12) Patent Application Publication
(10) Pub. No.: US 2022/0320405 A1
(43) Pub. Date: Oct. 6, 2022

(54) THERMOELECTRIC DEVICE

(71) Applicant: LG INNOTEK CO., LTD., Seoul (KR)

(72) Inventors: Jeung Ook PARK, Seoul (KR); Seung Yong LEE, Seoul (KR); Seok Min JIN, Seoul (KR)

(21) Appl. No.: 17/633,638

(22) PCT Filed: Aug. 4, 2020
(86) PCT No.: PCT/KR2020/010258

§ 371 Date: Feb. 8, 2022

(30) Foreign Application Priority Data
Aug. 9, 2019 (KR) 10-2019-0097578

(51) Int. Cl. H01L 35/04; H01L 35/30

(52) U.S. Cl. CPC H01L 35/04; H01L 35/30

(57) ABSTRACT

A thermoelectric apparatus according to one exemplary embodiment of the present invention includes a heat dissipation member having a groove formed therein, a first electrode disposed in the groove, a semiconductor structure disposed on the first electrode, a second electrode disposed on the semiconductor structure, a substrate disposed on the second electrode, and a sealing member disposed between a sidewall of the groove and the substrate.

### TECHNICAL FIELD

The present invention relates to a thermoelectric apparatus, and more particularly, to a structure of a thermoelectric apparatus.

### BACKGROUND ART

A thermoelectric effect is a phenomenon which occurs due to movement of electrons and holes in a material and refers to a direct energy conversion between heat and electricity.

Thermoelectric elements are generally referred to as elements using the thermoelectric effect, and the thermoelectric elements have a structure in which a P-type thermoelectric material and an N-type thermoelectric material are bonded between metal electrodes to form PN junction pairs.

The thermoelectric elements may be classified into elements using a change in electrical resistance according to a change in temperature, elements using a Seebeck effect which is a phenomenon in which an electromotive force is generated due to a temperature difference, elements using a Peltier effect which is a phenomenon in which heat absorption or heat emission occurs due to a current, and the like.

The thermoelectric elements have been variously applied to home appliances, electronic components, communication components, and the like. For example, the thermoelectric elements may be applied to cooling apparatuses, heating apparatuses, power generation apparatuses, and the like.

The thermoelectric element includes substrates, electrodes, and thermoelectric legs. The plurality of thermoelectric legs are disposed in an array form between an upper substrate and a lower substrate. A plurality of upper electrodes are disposed between the plurality of thermoelectric legs and the upper substrate. A plurality of lower electrodes are disposed between the plurality of thermoelectric legs and the lower substrate.

Meanwhile, when the thermoelectric element is applied to a cooling apparatus or a heating apparatus, a heat dissipation member may be disposed on a high temperature portion of the thermoelectric element. In order to bond the heat dissipation member to the high temperature portion, thermal grease may be disposed between a substrate of the high temperature portion and the heat dissipation member to bond the heat dissipation member to the high temperature portion, but thermal resistance may be increased due to the thermal grease, and a manufacturing process may be complicated.

### DISCLOSURE

### Technical Problem

The present invention is directed to providing a structure of a thermoelectric apparatus which has low thermal resistance and of which a manufacturing process is simple.

### Technical Solution

According to one exemplary embodiment of the present invention, a thermoelectric apparatus includes a heat dissipation member having a groove formed therein, a first electrode disposed in the groove, a semiconductor structure disposed on the first electrode, a second electrode disposed on the semiconductor structure, a substrate disposed on the second electrode, and a sealing member disposed between a sidewall of the groove and the substrate.

The thermoelectric apparatus may further include a first insulating layer disposed between a bottom surface of the groove and the first electrode to be in direct contact with the bottom surface of the groove, and a second insulating layer disposed between the second electrode and the substrate.

A height of the sidewall based on the bottom surface may be less than or equal to a sum of a thickness of the first insulating layer, a thickness of the first electrode, thicknesses of a P-type thermoelectric leg and an N-type thermoelectric leg, a thickness of the second electrode, and a thickness of the second insulating layer.

The substrate may extend from an edge of the second insulating layer to at least between an inner wall surface and an outer wall surface of the sidewall in a horizontal direction parallel to the second insulating layer, and the sealing member may be disposed between an upper surface of the sidewall and a lower surface of the substrate.

The sealing member may include a first sealing member disposed on the upper surface of the sidewall, a second sealing member disposed on the outer wall surface of the sidewall, and a third sealing member disposed on the inner wall surface of the sidewall, and the first sealing member, the second sealing member, and the third sealing member may be integrally formed.

An outermost edge of the substrate may be disposed on the upper surface of the sidewall.

An outermost edge of the substrate may bedisposed to extend outward further than a boundary between the upper surface and the outer wall surface of the sidewall.

An outermost edge of the substrate may be disposed to cover a portion of the outer wall surface of the sidewall.

An edge of the first insulating layer may be spaced apart from an inner wall surface of the sidewall.

A fluid may flow inside the heat dissipation member.

A sum of the height of the sidewall and a thickness of the sealing member based on the bottom surface may be less than or equal to 100 times the thickness of the first insulating layer.

A distance to the bottom surface from another surface opposite to one surface of the heat dissipation member may be three to twenty times a thickness of the substrate.

Cooling water may flow inside the heat dissipation member.

A plurality of heat dissipation fins may be disposed on the another surface opposite to the one surface of the heat dissipation member.

A plurality of heat dissipation fins may be disposed on the outer wall surface of the sidewall.

Each of heights of the second sealing member and the third sealing member may be 0.01 to 0.2 times the height of the sidewall based on the bottom surface.

An edge of the first insulating layer may be in contact with the inner wall surface of the sidewall.

### Advantageous Effects

According to exemplary embodiments of the present invention, it is possible to obtain a thermoelectric apparatus which has low thermal resistance so as to have excellent performance and high reliability and which is easy to manufacture. In addition, according to the exemplary embodiments of the present invention, it is possible to obtain a thermoelectric apparatus having excellent waterproof and dustproof performance and improved thermal flow performance.

A thermoelectric element according to exemplary embodiments of the present invention can be applied not only to application apparatuses implemented in a small size but also to applications apparatuses implemented in a large size, such as vehicles, ships, steelworks, and incinerators.

### DESCRIPTION OF DRAWINGS

FIGS. 1A and 1B show cross-sectional views of a thermoelectric element.

FIG. 2 is a perspective view of the thermoelectric element.

FIG. 3 is a cross-sectional view of a thermoelectric apparatus according to one exemplary embodiment of the present invention.

FIG. 4 is a cross-sectional view of a thermoelectric apparatus according to another exemplary embodiment of the present invention.

FIG. 5 is a top view of a portion of the thermoelectric apparatus of FIG. 4.

FIGS. 6 and 7 are cross-sectional views of a thermoelectric apparatus according to another exemplary embodiment of the present invention.

FIG. 8 is a cross-sectional view of a thermoelectric apparatus according to still another exemplary embodiment of the present invention.

FIGS. 9 to 11 are cross-sectional views of a thermoelectric apparatus according to yet another exemplary embodiment of the present invention.

FIG. 12 is a cross-sectional view of a thermoelectric apparatus according to yet another exemplary embodiment of the present invention.

### MODES OF THE INVENTION

Hereinafter, exemplary embodiments of the present invention will be described in detail with reference to the accompanying drawings.

However, the technical spirit of the present invention is not limited to some exemplary embodiments disclosed below but can be implemented in various different forms. Without departing from the technical spirit of the present invention, one or more of components may be selectively combined and substituted to be used between the exemplary embodiments.

Also, unless defined otherwise, terms (including technical and scientific terms) used herein may be interpreted as having the same meaning as commonly understood by one of ordinary skill in the art to which the present invention belongs. General terms like those defined in a dictionary may be interpreted in consideration of the contextual meaning of the related technology.

Furthermore, the terms used herein are intended to illustrate exemplary embodiments, but are not intended to limit the present invention.

In the present specification, the terms in singular form may include the plural forms unless otherwise specified. When “at least one (or one or more) of A, B, and C” is expressed, it may include one or more of all possible combinations of A, B, and C.

In addition, terms such as “first,” “second,” “A,” “B,” “(a),” and “(b)” may be used herein to describe components of the exemplary embodiments of the present invention.

Each of the terms is not used to define an essence, order, or sequence of a corresponding component but used merely to distinguish the corresponding component from other components.

In a case in which one component is described as being “connected,” “coupled,” or “joined” to another component, such a description may include both a case in which one component is “connected,” “coupled,” and “joined” directly to another component and a case in which one component is “connected,” “coupled,” and “joined” to another component with still another component disposed between one component and another component.

In a case in which any one component is described as being formed or disposed “on (or under)” another component, such a description includes both a case in which the two components are formed to be in direct contact with each other and a case in which the two components are in indirect contact with each other such that one or more other components are interposed between the two components. In addition, in a case in which one component is described as being formed “on (or under)” another component, such a description may include a case in which the one component is formed at an upper side or a lower side with respect to another component.

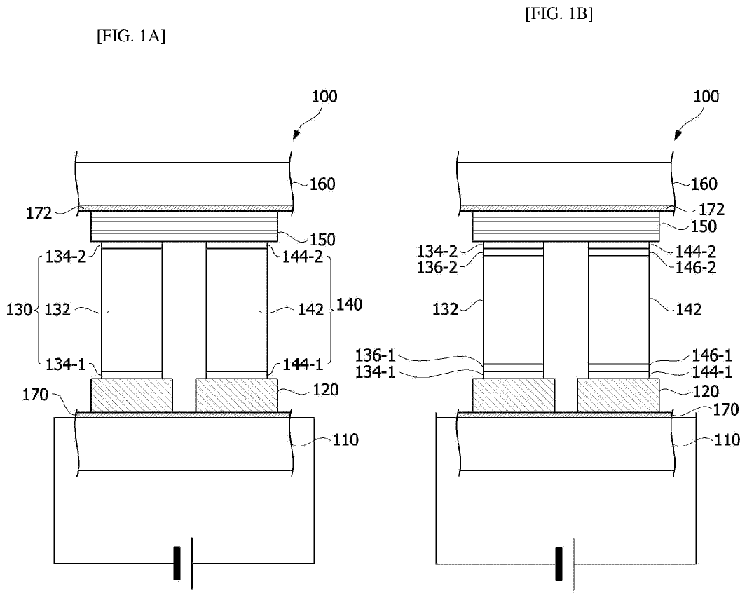

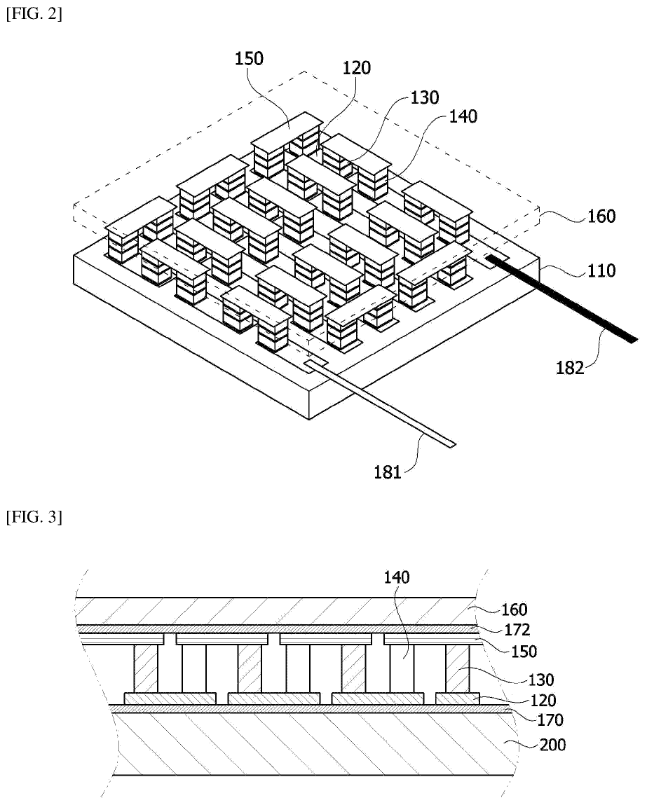

FIG. 1 shows cross-sectional views of a thermoelectric element, and FIG. 2 is a perspective view of the thermoelectric element.

Referring to FIGS. 1 and 2, a thermoelectric element 100 includes a lower substrate 110, lower electrodes 120, P-type thermoelectric legs 130, N-type thermoelectric legs 140, upper electrodes 150, and an upper substrate 160.

The lower electrodes 120 are disposed between the lower substrate 110 and lower bottom surfaces of the P-type thermoelectric leg 130 and the N-type thermoelectric leg 140, and the upper electrodes 150 are disposed between the upper substrate 160 and upper bottom surfaces of the P-type thermoelectric leg 130 and the N-type thermoelectric leg 140. Accordingly, a plurality of P-type thermoelectric legs 130 and a plurality of N-type thermoelectric legs 140 are electrically connected by the lower electrodes 120 and the upper electrodes 150. A pair of P-type thermoelectric leg 130 and N-type thermoelectric leg 140, which are disposed between the lower electrode 120 and the upper electrode 150 and are electrically connected, may form a unit cell.

For example, when a voltage is applied to the lower electrode 120 and the upper electrode 150 through lead wires 181 and 182, due to a Peltier effect, a substrate, in which a current flows from the P-type thermoelectric leg 130 to the N-type thermoelectric leg 140, may absorb heat to serve as a cooling portion, and a substrate, in which a current flows from the N-type thermoelectric leg 140 to the P-type thermoelectric leg 130, may be heated to serve as a heating portion. Alternatively, when a temperature difference occurs between the lower electrode 120 and the upper electrode 150, due to a Seebeck effect, electric charges may be moved in the P-type thermoelectric leg 130 and the N-type thermoelectric leg 140, and thus, electricity may also be generated.

Here, the P-type thermoelectric leg 130 and the N-type thermoelectric leg 140 may be bismuth fluoride (Bi-Te)-based thermoelectric legs including bismuth (Bi) and tellurium (Te) as main raw materials. The P-type thermoelectric leg 130 may be a Bi-Te-based thermoelectric leg including at least one selected from among antimony (Sb), nickel (Ni), aluminum (Al), copper (Cu), silver (Ag), lead (Pb), boron (B), gallium (Ga), tellurium (Te), bismuth (Bi), and indium (In). The P-type thermoelectric leg 130 may include Bi—Sb—Te, that is, a main material, at 99 wt % to 99.999 wt % and at least one selected from among nickel (Ni), aluminum (Al), copper (Cu), silver (Ag), lead (Pb), boron (B), gallium (Ga), and indium (In) at 0.001 wt % to 1 wt % with respect to a total weight of 100 wt %. The N-type thermoelectric leg 140 may be a Bi-Te-based thermoelectric leg including at least one selected from among selenium (Se), nickel (Ni), aluminum (Al), copper (Cu), silver (Ag), lead (Pb), boron (B), gallium (Ga), tellurium (Te), bismuth (Bi), and indium (In). For example, the N-type thermoelectric leg 140 may include Bi—Se—Te, that is, a main material, at 99 wt % to 99.999 wt % and at least one selected from among nickel (Ni), aluminum (Al), copper (Cu), silver (Ag), lead (Pb), boron (B), gallium (Ga), and indium (In) at 0.001 wt % to 1 wt % with respect to a total weight of 100 wt %.

Accordingly, in the present specification, a thermoelectric leg may also be referred to as a thermoelectric structure, a semiconductor structure, a semiconductor element, or the like.

The P-type thermoelectric leg 130 and the N-type thermoelectric leg 140 may be formed as a bulk type or a stacked type. In general, the bulk P-type thermoelectric leg 130 or the bulk N-type thermoelectric leg 140 may be obtained through a process of heat-treating a thermoelectric material to make an ingot, pulverizing and sieving the ingot to obtain a thermoelectric leg powder, sintering the thermoelectric leg powder, and then cutting the sintered body. In this case, the P-type thermoelectric leg 130 and the N-type thermoelectric leg 140 may be polycrystalline thermoelectric legs. For a polycrystalline thermoelectric leg, when a thermoelectric leg powder is sintered, the thermoelectric leg powder may be compressed at a pressure ranging from 100 MPa to 200 MPa. For example, when the P-type thermoelectric leg 130 is sintered, the thermoelectric leg powder may be sintered at a pressure ranging from 100 Mpa to 150 MPa, preferably, at a pressure ranging from 110 MPa to 140 MPa, and more preferably, at a pressure ranging from 120 Mpa to 130 MPa. When the N-type thermoelectric leg 130 is sintered, the thermoelectric leg powder may be sintered at a pressure ranging from 150 MPa to 200 MPa, preferably, at a pressure ranging from 160 MPa to 195 MPa, and more preferably, at a pressure ranging from 170 MPa to 190 MPa. As described above, when the P-type thermoelectric leg 130 and the N-type thermoelectric leg 140 are the polycrystalline thermoelectric legs, a strength of the P-type thermoelectric leg 130 and the N-type thermoelectric leg 140 may be increased. The stacked P-type thermoelectric leg 130 or the stacked N-type thermoelectric leg 140 may be obtained through a process of applying a paste including a thermoelectric material on a sheet-shaped substrate to form a unit member and then stacking and cutting the unit member.

In this case, a pair of P-type thermoelectric leg 130 and N-type thermoelectric leg 140 may have the same shape and volume or may have different shapes and volumes. For example, since the P-type thermoelectric leg 130 and the N-type thermoelectric leg 140 have different electrical conduction characteristics, a height or cross-sectional area of the N-type thermoelectric leg 140 may be different from a height or cross-sectional area of the P-type thermoelectric leg 130.

The P-type thermoelectric leg 130 or the N-type thermoelectric leg 140 may have a cylindrical shape, a polygonal pillar shape, an elliptical pillar shape, or the like.

Alternatively, the P-type thermoelectric leg 130 or the N-type thermoelectric leg 140 may have a stacked structure. For example, a P-type thermoelectric leg or an N-type thermoelectric leg may be formed through a method of stacking a plurality of structures coated with a semiconductor material on a sheet-shaped substrate and cutting the substrate. As a result, it is possible to prevent a loss of a material and improve electrical conduction characteristics. Each structure may further include a conductive layer having an opening pattern, and thus, it is possible to increase adhesion between the structures, decrease thermal conductivity, and increase electrical conductivity.

Alternatively, in the P-type thermoelectric legs 130 or the N-type thermoelectric legs 140, one thermoelectric leg may be formed to have different cross-sectional areas. For example, in one thermoelectric leg, a cross-sectional area of both ends thereof, which are disposed to face electrodes, may be greater than a cross-sectional area between the both ends. Accordingly, since a temperature difference between the both ends can be greatly formed, thermoelectric efficiency can be increased.

A performance of a thermoelectric element according to one exemplary embodiment of the present invention may be represented by a thermoelectric figure of merit (ZT). A thermoelectric figure of merit (ZT) may be represented by Example 1.

ZT=α²·σ·T/k [Equation 1]

In Equation 1, a refers to a Seebeck coefficient [V/K], σ refers to electrical conductivity [S/m], and α2·σ refers to a power factor [W/mK2]. T refers to a temperature and k refers to thermal conductivity [W/mK]. k may be represented by a·cp·p. Here, a refers to thermal diffusivity [cm2/S], cp refers to specific heat [J/gK], and p refers to a density [g/cm3].

In order to obtain a thermoelectric figure of merit of a thermoelectric element, a Z value (V/K) may be measured using a Z meter, and the thermoelectric figure of merit (ZT) may be calculated using the measured Z value.

Here, the lower electrode 120 disposed between the lower substrate 110, and the P-type thermoelectric leg 130 and the N-type thermoelectric leg 140, and the upper electrode 150 disposed between the upper substrate 160, and the P-type thermoelectric leg 130 and the N-type thermoelectric legs 140 may include at least one selected from among copper (Cu), silver (Ag), aluminum (Al), and nickel (Ni) and may have a thickness ranging from 0.01 mm to 0.3 mm. When the thickness of the lower electrode 120 or the upper electrode 150 is less than 0.01 mm, a function as an electrode may be degraded, and electrical conductivity may be lowered. When the thickness is more than 0.3 mm, conduction efficiency may be lowered due to an increase in resistance.

The lower substrate 110 and the upper substrate 160 opposite to each other may be metal substrates and may have a thickness ranging from 0.1 mm to 1.5 mm. When the thickness of the metal substrate is less than 0.1 mm or more than 1.5 mm, heat dissipation characteristics or thermal conductivity may be excessively high such that reliability of the thermoelectric element may be lowered. In addition, when the lower substrate 110 and the upper substrate 160 are the metal substrates, insulating layers 170 and 172 may be further formed between the lower substrate 110 and the lower electrode 120 and between the upper substrate 160 and the upper electrode 150. The insulating layers 170 and 172 may include a material having a thermal conductivity of 5 W/K to 20 W/K.

Meanwhile, the P-type thermoelectric leg 130 and the N-type thermoelectric leg 140 may have a structure shown in FIG. 1A or 1B. Referring to FIG. 1A, the thermoelectric legs 130 and 140 may include thermoelectric material layers 132 and 142, first plating layers 134-1 and 144-1 stacked on one surfaces of the thermoelectric material layers 132 and 142, and second plating layers 134-2 and 144-2 stacked on the other surfaces disposed opposite to one surfaces of the thermoelectric material layers 132 and 142. Alternatively, referring to FIG. 1B, the thermoelectric legs 130 and 140 may include thermoelectric material layers 132 and 142, first plating layers 134-1 and 144-1 stacked on one surfaces of the thermoelectric material layers 132 and 142, second plating layers 134-2 and 144-2 stacked on the other surfaces disposed opposite to one surfaces of the thermoelectric material layers 132 and 142, and first buffer layers 136-1 and 146-1 and second buffer layers 136-2 and 146-2 disposed between the thermoelectric material layers 132 and 142 and the first plating layers 134-1 and 144-1 and between the thermoelectric material layers 132 and 142 and the second plating layers 134-2 and 146-2. Alternatively, the thermoelectric legs 130 and 140 may further include metal layers stacked between the first plating layers 134-1 and 144-1 and the lower substrate 110 and between the second plating layers 134-2 and 144-2 and the upper substrate 160.

Here, the thermoelectric material layers 132 and 142 may include bismuth (Bi) and tellurium (Te) which are semiconductor materials. The thermoelectric material layers 132 and 142 may have the same material or shape as the P-type thermoelectric leg 130 or N-type thermoelectric leg 140. When the thermoelectric material layers 132 and 142 are polycrystalline layers, it is possible to increase adhesion between the thermoelectric material layers 132 and 142, and the first buffer layers 136-1 and 146-1 and the first plating layers 134-1 and 144-1, and adhesion between the thermoelectric material layers 132 and 142, and the second buffer layers 136-2 and 146-2 and the second plating layers 134-2 and 144-2. Accordingly, even when the thermoelectric element 100 is applied to application apparatuses, such as vehicles in which vibration is generated, it is possible to prevent the first plating layer 134-1 or 144-1 and the second plating layer 134-2 or 144-2 from being separated from the P-type thermoelectric leg 130 or the N-type thermoelectric leg 140 to be carbonized, and it is possible to increase durability and reliability of the thermoelectric element 100.

The metal layer may be made of one selected from among copper (Cu), a copper alloy, aluminum (Al), and an aluminum alloy and may have a thickness ranging from 0.1 mm to 0.5 mm, and preferably, a thickness ranging from 0.2 mm to 0.3 mm.

Next, each of the first plating layers 134-1 and 144-1 and the second plating layers 134-2 and 144-2 may include at least one selected from among nickel (Ni), tin (Sn), titanium (Ti), iron (Fe), antimony (Sb), chromium (Cr), and molybdenum (Mo) and may have a thickness ranging from 1 μm to 20 μm, and preferably, a thickness ranging from 1 μm to 10 μm. Since the first plating layers 134-1 and 144-1 and the second plating layers 134-2 and 144-2 prevent a reaction between the metal layer and Bi or Te which is the semiconductor material in the thermoelectric material layers 132 and 142, it is possible to not only prevent performance degradation of the thermoelectric element but also to prevent oxidation of the metal layer.

In this case, the first buffer layers 136-1 and 146-1 and the second buffer layers 136-2 and 146-2 may be disposed between the thermoelectric material layers 132 and 142 and the first plating layers 134-1 and 144-1 and between the thermoelectric material layers 132 and 142 and the second plating layers 134-2 and 146-2. In this case, the first buffer layers 136-1 and 146-1 and the second buffer layers 136-2 and 146-2 may include Te. For example, the first buffer layers 136-1 and 146-1 and the second buffer layers 136-2 and 146-2 may include at least one selected from among Ni—Te, Sn—Te, Ti—Te, Fe—Te, Sb—Te, Cr—Te, and Mo—Te. According to the exemplary embodiments of the present invention, when the first buffer layers 136-1 and 146-1 and the second buffer layers 136-2 and 146-2, which include Te, are disposed between the thermoelectric material layers 132 and 142 and the first plating layers 134-1 and 144-1 and between the thermoelectric material layers 132 and 142 and the second plating layers 134-2 and 146-2, it is possible to prevent Te in the thermoelectric material layers 132 and 142 from diffusing into the first plating layers 134-1 and 144-1 and the second plating layers 134-2 and 144-2. Accordingly, it is possible to prevent an increase in electrical resistance in the thermoelectric material layer due to a Bi-rich region.

Although the terms “lower substrate 110,” “lower electrode 120,” “upper electrode 150,” and “upper substrate 160” have been used, the terms “upper” and “lower” are merely arbitrarily used for ease of understanding and convenience of description, and positions may be reversed such that the lower substrate 110 is disposed above the lower electrode 120 and the upper electrode 150 is disposed below the upper substrate 160.

In the present specification, for convenience of description, an example will be described in which the lower substrate 110 and the lower electrode 120 are a high temperature portion of the thermoelectric element 100, and the upper substrate 160 and the upper electrode 150 are a low temperature portion of the thermoelectric element 100.

A heat dissipation member may be disposed on the high temperature portion of the thermoelectric element 100, for example, the lower substrate 110. To this end, the lower substrate 110 and the heat dissipation member may be bonded using thermal grease. However, due to an interface between the insulating layer 170 and the lower substrate 110, an interface between the lower substrate 110 and the thermal grease, and an interface between the thermal grease and the heat dissipation member, there is a problem in that a thermal resistance of the high temperature portion is increased.

According to the exemplary embodiments of the present invention, in order to solve the problem, the substrate of the high temperature portion is omitted, and the insulating layer and the heat dissipation member are to be directly bonded.

FIG. 3 is a cross-sectional view of a thermoelectric apparatus according to one exemplary embodiment of the present invention.

Referring to FIG. 3, the thermoelectric apparatus includes a heat dissipation member 200, a first insulating layer 170 in direct contact with the heat dissipation member 200, a first electrode 120 disposed on the first insulating layer 170, a P-type thermoelectric leg 130 and an N-type thermoelectric leg 140 which are disposed on the first electrode 120, a second electrode 150 disposed on the P-type thermoelectric leg 130 and the N-type thermoelectric leg 140, a second insulating layer 172 disposed on the second electrode 150, and a substrate 160 disposed on the second insulating layer 172.

Here, detailed descriptions of the first insulating layer 170, the first electrode 120, the P-type thermoelectric leg 130 and N-type thermoelectric leg 140, the second electrode 150, the second insulating layer 172, and the substrate 160 are the same as the descriptions of the insulating layer 170, the first electrode 120, the P-type thermoelectric leg 130 and N-type thermoelectric leg 140, the second electrode 150, the insulating layer 172, and the upper substrate 160 of FIGS. 1 and 2, and thus, redundant descriptions will be omitted.

The heat dissipation member 200 may be a member that dissipates heat of a high temperature portion and may be made of a metal material having high thermal conductivity.

In order for the heat dissipation member 200 and the first insulating layer 170 to be in direct contact with each other, the first insulating layer 170 may be a resin layer having all of adhesion performance, thermal conduction performance, and insulating performance. In order for the heat dissipation member 200 and the first insulating layer 170 to be in direct contact with each other, an uncured or semi-cured resin layer may be applied on a surface of the heat dissipation member 200 and then compressed and cured.

In this case, the first insulating layer 170 may be formed as a resin layer which includes at least one selected from among an epoxy resin composition including an epoxy resin and an inorganic filler and a silicone resin composition including polydimethylsiloxane (PDMS). Accordingly, the first insulating layer 170 may improve an insulating property, adhesion, and thermal conduction performance between the heat dissipation member 200 and the first electrode 120.

Here, the inorganic filler may be included in the resin layer in an amount ranging from 68 vol % to 88 vol %. When the inorganic filler is included in an amount less than 68 vol %, a heat conduction effect may be low. When the inorganic filler is included in an amount exceeding 88 vol %, the resin layer may be easily broken.

The epoxy resin may include an epoxy compound and a curing agent. In this case, the curing agent may be included at 1 to 10 parts by volume with respect to 10 parts by volume of the epoxy compound. Here, the epoxy compound may include at least one selected from among a crystalline epoxy compound, an amorphous epoxy compound, and a silicone epoxy compound. The inorganic filler may include aluminum oxide and a nitride, and the nitride may be included in the inorganic filler in an amount ranging from 55 wt % to 95 wt %, and more preferably, in an amount ranging from 60 wt % to 80 wt %. When the nitride is included in the numerical range, it is possible to increase thermal conductivity and bonding strength. Here, the nitride may include at least one selected from boron nitride and aluminum nitride.

In this case, a particle size (D50) of a boron nitride agglomerate may range from 250 μm to 350 μm, and a particle size (D50) of the aluminum oxide may range from 10 μm to 30 μm. When the particle size (D50) of a boron nitride agglomerate and the particle size (D50) of the aluminum oxide are within such numerical ranges, the boron nitride agglomerate and the aluminum oxide may be uniformly dispersed in the resin layer, thereby uniformly providing a heat conduction effect and adhesion performance throughout the resin layer.

The heat dissipation member 200 may be made of a material that is the same as or different from a material of the substrate 160. Meanwhile, the heat dissipation member 200 may be thicker than the substrate 160 so as to have both structural stability and a heat dissipation function. For example, a thickness of the heat dissipation member 200 may be three to twenty times a thickness of the substrate 160. Accordingly, in spite of a frequent thermal expansion of the high temperature portion, since a width, which expands in a plane direction perpendicular to a thickness direction of the heat dissipation member 200, is reduced, it is possible to minimize delamination of an interface between the heat dissipation member 200 and the first insulating layer 170.

The substrate 160 may have a flat plate shape, but the heat dissipation member 200 may be processed into a certain shape so as to dissipate heat.

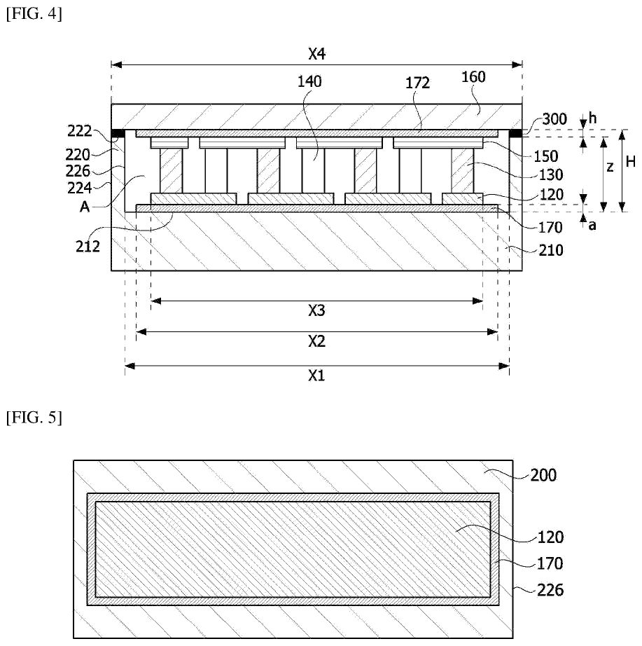

FIG. 4 is a cross-sectional view of a thermoelectric apparatus according to another exemplary embodiment of the present invention. Redundant descriptions of the same contents as those described with reference to FIGS. 1 to 3 will be omitted.

Referring to FIG. 4, a heat dissipation member 200 includes a bottom portion 210 and a sidewall 220 disposed in a direction perpendicular to the bottom portion 210. That is, a groove A, which includes a bottom surface 212, that is, one surface of the heat dissipation member 200, and the sidewall 220 surrounding the bottom surface 212, is formed in one surface of the heat dissipation member 200. In the present specification, in the sidewall 220, a surface facing upward is referred to as an upper surface 222 of the sidewall 220, a surface facing outside the groove A is referred to as an outer wall surface 224 of the sidewall 220, and a surface facing inside the groove A is referred to as an inner wall surface 226 of the sidewall 220.

Meanwhile, a first insulating layer 170 may be in direct contact with the bottom surface 212 of the heat dissipation member 200. At least portions of the insulating layer 170, a first electrode 120, a P-type thermoelectric leg 130 and N-type thermoelectric leg 140, a second electrode 150, and a second insulating layer 172 may be surrounded by the inner wall surface 226 of the sidewall 220 of the heat dissipation member 200. A substrate 160 may be disposed to cover the sidewall 220 of the heat dissipation member 200, the first insulating layer 170, the first electrode 120, the P-type thermoelectric leg 130 and N-type thermoelectric leg 140, the second electrode 150, and the second insulating layer 172.

In this case, a maximum width X4 of the substrate 160 may be greater than a maximum width X1 between the inner wall surfaces 226 of the sidewall 220. That is, the substrate 160 may extend from an edge of the second insulating layer 172 to at least between the inner wall surface 226 and the outer wall surface 224 of the sidewall 220 in a horizontal direction parallel to the second insulating layer 172. Accordingly, the substrate 160 may be disposed on the sidewall 220 of the heat dissipation member 200. In this case, a surface of two surfaces of the substrate 160, which is in contact with the upper surface 222 of the sidewall 220, may have a flat shape. Accordingly, bonding between the substrate 160 and the sidewall 220 is easy. As shown in FIG. 5, the maximum width X1 between the inner wall surfaces 226 of the sidewall 220 may be greater than or equal to a maximum width X2 of the first insulating layer 170, and the maximum width X2 of the first insulating layer 170 may be greater than a maximum width X3 of the first electrode 120. The inner wall surface 226 of the sidewall 220 and the first electrode 120 may be spaced apart from each other by a distance of at least 0.05 mm. Accordingly, the heat dissipation member 200 and the first electrode 120 may be safely insulated from each other.

As described above, when the sidewall 220 of the heat dissipation member 200 supports the substrate 160, mechanical stability of the thermoelectric apparatus can be improved. In addition, when at least portions of the first insulating layer 170, the first electrode 120, the P-type thermoelectric leg 130 and N-type thermoelectric leg 140, the second electrode 150, and the second insulating layer 172 are surrounded by the inner wall surface 226 of the sidewall 220 of the heat dissipation member 200, spaces between the first insulating layer 170, the first electrode 120, the P-type thermoelectric leg 130 and N-type thermoelectric leg 140, the second electrode 150, and the second insulating layer 172 may be left empty without needing to be filled with a resin or the like, and thus, heat flow performance of the thermoelectric apparatus can be improved.

In this case, a height z of the sidewall 220 based on the bottom surface 212 of the heat dissipation member 200 may be less than or equal to the sum of a thickness of the first insulating layer 170, a thickness of the first electrode 120, thicknesses of the P-type thermoelectric leg 130 and N-type thermoelectric legs 140, a thickness of the second electrode 150, and a thickness of the second insulating layer 172. Accordingly, the substrate 160 may be stably bonded to the sidewall 220 of the heat dissipation member 200.

Meanwhile, the thermoelectric apparatus according to the exemplary embodiment of the present invention may further include a sealing member 300 disposed between the substrate 160 and the sidewall 220 of the heat dissipation member 200. As described above, when the sealing member 300 is disposed between the substrate 160 and the heat dissipation member 200, moisture or the like can be prevented from permeating into the thermoelectric apparatus, and cold heat of a low temperature portion can be prevented from being lost through a high temperature portion due to a contact between the substrate 160 and the heat dissipation member 200, that is, due to a contact between the low temperature portion and the high temperature portion, thereby preventing performance degradation of an thermoelectric element.

In this case, the sealing member 300 disposed on the upper surface 222 of the sidewall 220 of the heat dissipation member 200 may have a thickness of 0.05 mm or more. Accordingly, the sealing between the sidewall 220 of the heat dissipation member 200 and the substrate 160 can be stably maintained.

In addition, when the thickness of the first insulating layer 170 is a, the thickness of the first electrode 120 may range from 2 a to 12 a, the thickness of the P-type thermoelectric leg 130 and the N-type thermoelectric leg 140 may range from 20 a to 40 a, the thickness of the second electrode 150 may range from 2 a to 12 a, and the thickness of the second insulating layer 172 may range from 0.8 a to 2 a. Accordingly, a sum H of the height z of the sidewall 220 and a thickness h of the sealing member 300 based on the bottom surface 212 of the heat dissipation member 200 may be less than or equal to 100 times, preferably, 80 times, and more preferably, 67 times the thickness of the first insulating layer 170. Accordingly, the sidewall 220 of the heat dissipation member 200 and the substrate 160 can be stably bonded, thereby improving structural stability and thermoelectric performance of the thermoelectric apparatus.

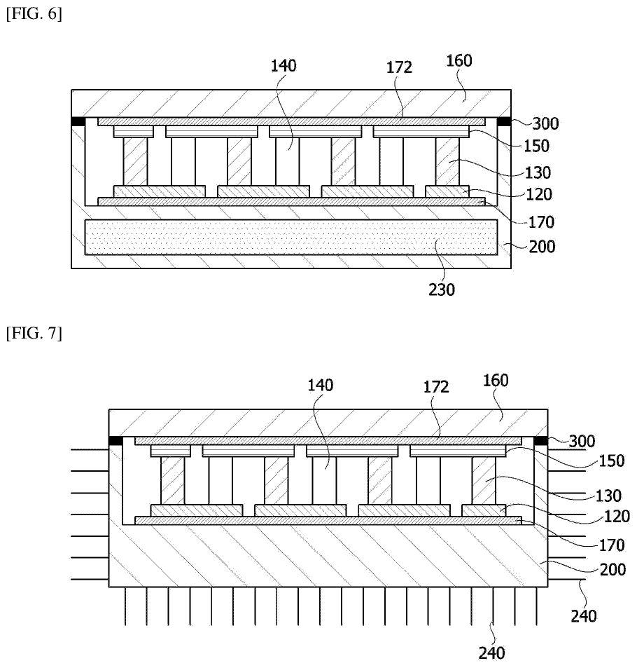

FIGS. 6 and 7 are cross-sectional views of a thermoelectric apparatus according to another exemplary embodiment of the present invention.

Referring to FIG. 6, a heat dissipation member 200 may be a cooler. That is, cooling water 230 may flow inside the heat dissipation member 200.

Alternatively, referring to FIG. 7, the heat dissipation member 200 may be a heat sink. That is, a plurality of heat dissipation fins 240 may be disposed on another surface opposite to a bottom surface 212 of the heat dissipation member 200. Alternatively, a plurality of heat dissipation fins 240 may be further disposed on a side surface of a bottom portion 210 of and an outer wall surface 224 of a sidewall 220 of the heat dissipation member 200.

Accordingly, heat dissipation performance of the heat dissipation member 200 can be further improved.

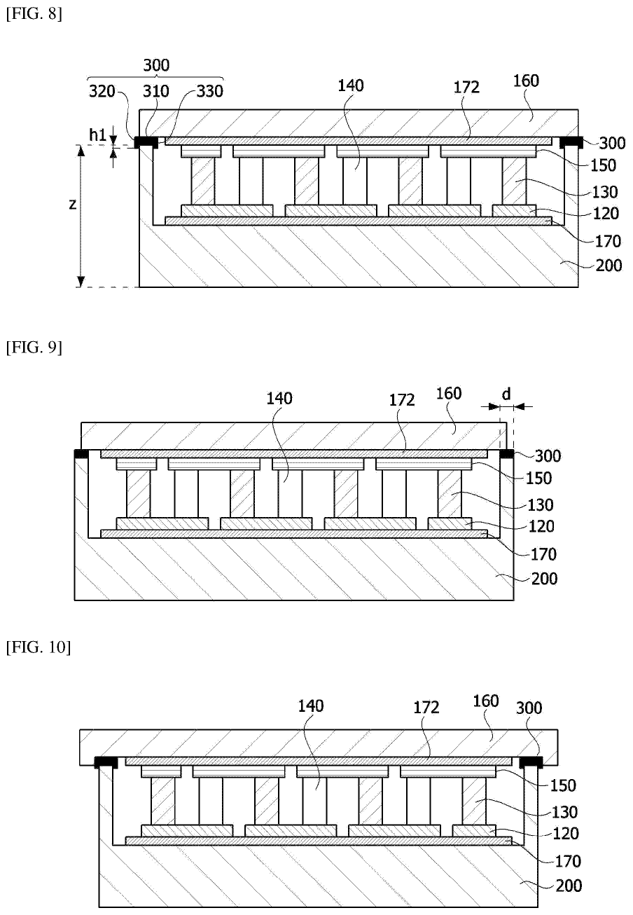

FIG. 8 is a cross-sectional view of a thermoelectric apparatus according to still another exemplary embodiment of the present invention.

Referring to FIG. 8, a sealing member 300 may include a first sealing member 310 disposed on an upper surface 222 of a sidewall 220, a second sealing member 320 disposed on an outer wall surface 224 of the sidewall 220, and a third sealing member 330 disposed on an inner wall surface 226 of the sidewall 220. The first sealing member 310, the second sealing member 320, and the third sealing member 330 may be integrally formed. As described above, when the sealing member 300 includes the first sealing member 310 as well as the second sealing member 320 and the third sealing member 330, it is possible to more airtightly seal a space between the sidewall 220 and a substrate 160, and it is possible to further lower a possibility that the sidewall 220 of the heat dissipation member 200 and the substrate 160 come into contact with each other due to abrasion of the sealing member.

In this case, each of heights hl of the second sealing member 320 and the third sealing member 330 may be 0.01 to 0.2 times a height z of the sidewall 220 based on a bottom surface 212. Accordingly, airtight sealing may be possible while heat dissipation performance is maintained through the sidewall 220.

FIGS. 9 to 11 are cross-sectional views of a thermoelectric apparatus according to yet another exemplary embodiment of the present invention.

Referring to FIG. 9, an outermost edge of the substrate 160 may be disposed on an upper surface 222 of a sidewall 220. For example, the outermost edge of the substrate 160 may be disposed to overlap the upper surface 222 of the sidewall 220 by more than a half of a width d.

Referring to FIG. 10, the outermost edge of the substrate 160 may be disposed to extend outward further than a boundary between the upper surface 222 and an outer wall surface 224 of the sidewall 220. For example, the outermost edge of the substrate 160 may also be disposed to further extend from an edge of the upper surface 222 of the sidewall 220 by a distance d′.

According to FIGS. 9 to 10, a cooling target having various areas or shapes may be disposed on the substrate 160 of a low temperature portion.

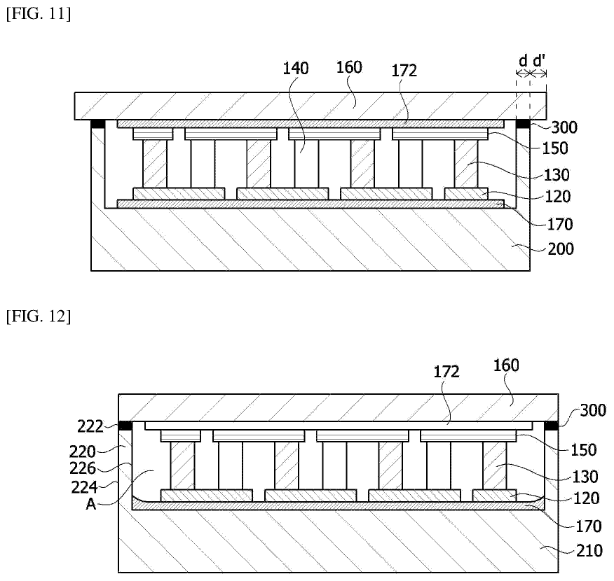

Alternatively, referring to FIG. 11, the outermost edge of the substrate 160 may be disposed to cover a portion of the outer wall surface 224 of the sidewall 220. Accordingly, the substrate 160 and the sidewall 220 may be more stably fixed, and since the substrate 160 is in contact with a first sealing member 310 as well as a second sealing member 320 and a third sealing member 330, it is possible to airtightly seal a space between the substrate 160 and the sidewall 220.

FIG. 12 is a cross-sectional view of a thermoelectric apparatus according to yet another exemplary embodiment of the present invention.

Referring to FIG. 12, an edge of a first insulating layer 170 may be in contact with an inner wall surface 226 of a sidewall 220. Accordingly, heat of a high temperature portion may be dissipated through the sidewall 220 as well as a bottom portion 210 of the heat dissipation member 200, and thus, heat dissipation performance can be further increased. In this case, a height of the first insulating layer 170 in contact with the inner wall surface 226 of the sidewall 220 may be decreased to a certain point away from the inner wall surface 226 of the sidewall 220. Accordingly, it is possible to reduce a possibility that the first electrode 120 may come into contact with the sidewall 220 of the heat dissipation member 200 made of a metal material.

Hereinafter, results of measuring thermal resistances of thermoelectric apparatuses according to Examples of the present invention and Comparative Examples will be described.

In Comparative Example 1, thermal resistances of a cooler, a substrate, an insulating layer, an electrode, and a thermoelectric leg having thicknesses and thermal conductivities as shown in Table 1 were calculated. In Example 1, thermal resistances of a structure, which is the same as that of Comparative Example 1 except that a substrate is omitted as shown in Table 2, were calculated.

In Comparative Example 2, thermal resistances of a cooler, a substrate, an insulating layer, an electrode, and a thermoelectric leg having thicknesses and thermal conductivities as shown in Table 3 were calculated. In Example 2, thermal resistances of a structure, which is the same as that of Comparative Example 2 except that a substrate is omitted as shown in Table 4, were calculated.

TABLE 1

| | | Thermal |
|---|---|---|
| | | conductivity |
| Structure | Thickness (mm) | (W/mK) |
| Thermoelectric leg | 25 | 100 |
| Electrode | 0.5 | 400 |
| Insulating layer | 0.2 | 0.5 |
| Substrate | 5 | 400 |
| Cooler | 30 | 100 |

TABLE 2

| | | Thermal |
|---|---|---|
| | | conductivity |
| Structure | Thickness (mm) | (W/mK) |
| Thermoelectric leg | 25 | 100 |
| Electrode | 0.5 | 400 |
| Insulating layer | 0.2 | 0.5 |
| Cooler | 25 | 100 |

TABLE 3

| | | Thermal |
|---|---|---|
| | | conductivity |
| Structure | Thickness (mm) | (W/mK) |
| Thermoelectric leg | 25 | 100 |
| Electrode | 0.5 | 400 |
| Insulating layer | 0.2 | 0.5 |
| Substrate | 2 | 17 |
| Cooler | 30 | 100 |

TABLE 4

| | | Thermal |
|---|---|---|
| | | conductivity |
| Structure | Thickness (mm) | (W/mK) |
| Thermoelectric leg | 25 | 100 |
| Electrode | 0.5 | 400 |
| Insulating layer | 0.2 | 0.5 |
| Cooler | 30 | 100 |

The thermal resistance was calculated as in Equation 2 below.

thermal resistance=L/(kA) [Equation 2]

In Equation 2, L refers to a thickness, k refers to thermal conductivity, and A refers to an area.

Accordingly, it could be seen that the thermal resistance of Example 1 was improved by about 8.5% as compared with Comparative Example 1 and the thermal resistance of Example 2 was improved by about 16.5% as compared with Comparative Example 2.

The thermoelectric element according to the exemplary embodiments of the present invention may be applied to power generation apparatuses, cooling apparatuses, heating apparatuses, and the like. Specifically, the thermoelectric element according to the exemplary embodiments of the present invention may be mainly applied to optical communication modules, sensors, medical instruments, measuring instruments, aerospace industrial fields, refrigerators, chillers, automotive ventilation sheets, cup holders, washers, dryers, wine cellars, water purifiers, sensor power supplies, thermopiles, and the like.

Here, as an example in which the thermoelectric element according to the exemplary embodiments of the present invention is applied to medical instruments, there are polymerase chain reaction (PCR) instruments. The PCR instrument is an apparatus, in which deoxyribonucleic acid (DNA) is amplified to determine a sequence of DNA, requiring precise temperature control and a thermal cycle. To this end, a Peltier-based thermoelectric element can be applied thereto.

As another example in which the thermoelectric element according to the exemplary embodiments of the present invention is applied to medical instruments, there are photodetectors. Here, the photodetectors include infrared/ultraviolet detectors, charge coupled device (CCD) sensors, X-ray detectors, and thermoelectric thermal reference sources (TTRS). The Peltier-based thermoelectric element may be applied for cooling the photodetector. Accordingly, a change in wavelength and decreases in output power and resolution due to an increase in temperature in the photodetector can be prevented.

As still another example in which the thermoelectric element according to the exemplary embodiments of the present invention is applied to medical instruments, there are an immunoassay field, an in vitro diagnostic field, temperature control and cooling systems, a physiotherapy field, liquid chiller systems, a blood/plasma temperature control field, and the like. Accordingly, a temperature can be precisely controlled.

As yet another example in which the thermoelectric element according to the exemplary embodiments of the present invention is applied to medical instruments, there are artificial hearts. Accordingly, power can be supplied to the artificial heart.

As an example in which the thermoelectric element according to the exemplary embodiments of the present invention is applied to an aerospace industrial field, there are star tracking systems, thermal imaging cameras, infrared/ultraviolet detectors, CCD sensors, the Hubble space telescope, TTRS, and the like. Accordingly, a temperature of an image sensor can be maintained.

As another example in which the thermoelectric element according to the exemplary embodiments of the present invention is applied to an aerospace industrial field, there are cooling apparatuses, heaters, power generation apparatuses, and the like.

In addition, the thermoelectric element according to the exemplary embodiments of the present invention may be applied to other industrial fields for power generation, cooling, and heating.

While the present invention has been shown and described with reference to the exemplary embodiments thereof, it will be understood by those skilled in the art that various changes in form and details may be made therein without departing from the spirit and scope of the present invention as defined by the appended claims.

1. A thermoelectric apparatus comprising:
a heat dissipation member having a groove formed therein;
a first electrode disposed in the groove;
a semiconductor structure disposed on the first electrode;
a second electrode disposed on the semiconductor structure;
a substrate disposed on the second electrode; and
a sealing member disposed between an upper surface of a sidewall of the groove and a lower surface of the substrate.

2. The thermoelectric apparatus of claim 1, further comprising:
a first insulating layer disposed between a bottom surface of the groove and the first electrode to be in direct contact with the bottom surface of the groove; and
a second insulating layer disposed between the second electrode and the substrate.

3. The thermoelectric apparatus of claim 2, wherein a height of the sidewall based on the bottom surface is less than or equal to a sum of a thickness of the first insulating layer, a thickness of the first electrode, thicknesses of a P-type thermoelectric leg and an N-type thermoelectric leg, a thickness of the second electrode, and a thickness of the second insulating layer.

4. The thermoelectric apparatus of claim 3, wherein the substrate extends from an edge of the second insulating layer to at least between an inner wall surface and an outer wall surface of the sidewall in a horizontal direction parallel to the second insulating layer.

5. The thermoelectric apparatus of claim 4, wherein the sealing member includes a first sealing member disposed on the upper surface of the sidewall, a second sealing member disposed on the outer wall surface of the sidewall, and a third sealing member disposed on the inner wall surface of the sidewall, and
the first sealing member, the second sealing member, and the third sealing member are integrally formed.

6. The thermoelectric apparatus of claim 4, wherein an outermost edge of the substrate is disposed on the upper surface of the sidewall.

7. The thermoelectric apparatus of claim 4, wherein an outermost edge of the substrate is disposed to extend outward further than a boundary between the upper surface and the outer wall surface of the sidewall.

8. The thermoelectric apparatus of claim 4, wherein an outermost edge of the substrate is disposed to cover a portion of the outer wall surface of the sidewall.

9. The thermoelectric apparatus of claim 1, wherein an edge of the first insulating layer is spaced apart from an inner wall surface of the sidewall.

10. The thermoelectric apparatus of claim 1, wherein a fluid flows inside the heat dissipation member.

11. The thermoelectric apparatus of claim 4, wherein a sum of the height of the sidewall and a thickness of the sealing member based on the bottom surface is less than or equal to 100 times the thickness of the first insulating layer.

12. The thermoelectric apparatus of claim 4, wherein a distance to the bottom surface from another surface opposite to one surface of the heat dissipation member is three to twenty times a thickness of the substrate.

13. The thermoelectric apparatus of claim 1, wherein cooling water flows inside the heat dissipation member.

14. The thermoelectric apparatus of claim 1, wherein a plurality of heat dissipation fins are disposed on the another surface opposite to the one surface of the heat dissipation member.

15. The thermoelectric apparatus of claim 14, wherein a plurality of heat dissipation fins are disposed on the outer wall surface of the sidewall.

16. The thermoelectric apparatus of claim 5, wherein each of heights of the second sealing member and the third sealing member is 0.01 to 0.2 times the height of the sidewall based on the bottom surface.

17. The thermoelectric apparatus of claim 4, wherein an edge of the first insulating layer may be in contact with the inner wall surface of the sidewall.

18. The thermoelectric apparatus of claim 17, wherein a height of the first insulating layer in contact with the inner wall surface of the sidewall is decreased to a certain point away from the inner wall surface of the sidewall.

19. The thermoelectric apparatus of claim 5, wherein an outermost edge of the substrate is disposed to cover a portion of the outer wall surface of the sidewall, and the third sealing member is disposed between the substrate and the outer wall surface of the sidewall.

20. A power generation apparatus comprising the thermoelectric apparatus according to claim 1.
